(19) United States
(12) Patent Application Publication
(10) Pub. No.: US 2026/0304810 A1
(43) Pub. Date: Oct. 1, 2026

(54) REDUCTION OF INTERFACE RESISTANCE BETWEEN SILICON NANOSHEETS AND HIGHLY DOPED SOURCE/DRAIN REGIONS IN NANOSHEET DEVICES

(71) Applicant: ASM IP Holding B.V., Almere (NL)

(72) Inventors: Daniel Casey, Herent (BE); Brendan Timothy Padraig Marozas, Leuven (BE)

(21) Appl. No.: 19/630,734

(22) Filed: Mar. 27, 2026

Related U.S. Application Data
(60) Provisional application No. 63/781,526, filed on Apr. 1, 2025.

(51) Int. Cl. H10D 30/01; H10D 30/00; H10D 62/10; H10D 62/832; H10P 14/20; H10P 14/24; H10P 50/24

(52) U.S. Cl. CPC H10D 30/0193; H10D 30/507; H10P 14/24; H10P 14/3442; H10P 14/3444; H10P 50/242; H10D 62/121; H10D 62/832; H10P 14/2905; H10P 14/3411

(57) ABSTRACT

Disclosed are methods and systems for silicon nanosheet etchback to reduce source/drain and silicon nanosheet interface resistance using epitaxial deposition methods in the same reaction chamber under the same process conditions. The etchback may be a Cl₂ thermal etchback.

### CROSS-REFERENCE TO RELATED APPLICATIONS

This application claims priority to U.S. Provisional Patent Application Ser. No. 63/781,526 filed Apr. 1, 2025 and titled REDUCTION OF INTERFACE RESISTANCE BETWEEN SILICON NANOSHEETS AND HIGHLY DOPED SOURCE/DRAIN REGIONS IN NANOSHEET DEVICES, the disclosure of which is hereby incorporated by reference in its entirety.

### FIELD

The present disclosure relates generally to the field of semiconductor processing methods and systems and to the field of device and integrated circuit manufacture. More specifically, the present disclosure generally relates to reducing the interface resistance between silicon nanosheets and highly doped source/drain regions in nanosheet devices.

### BACKGROUND

The scaling of semiconductor devices has led to significant improvements in the speed and density of integrated circuits. However, current fabrication methods of stacked nanosheets may exhibit interface resistance in the area between the silicon nanosheets and the highly doped source/drain regions of nanosheet devices. This interface resistance may degrade performance and lower maximum drive current which reduces overall power efficiency in finished nanosheet devices.

For instance, FIG. 1 illustrates a silicon nanosheet structure 105. The silicon nanosheet areas 107 between the silicon nanosheet inner spacers 109 experience minimal, if any, field effect in the finished transistor device. This creates a potential resistance bottleneck between the highly doped source/drain regions 111 and the gate-controlled region 113.

Current methods of attempting to reduce the interface resistance in nanosheet devices, such as PMOS devices, require the use of high-temperature spike anneals, increasing the number of process steps necessary to fabricate the logical devices. Accordingly, improved methods and systems for reducing the interface resistance in the area between the silicon nanosheets and the highly doped source/drain regions of nanosheet devices are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to silicon nanosheet etchback to reduce source/drain and silicon nanosheet interface resistance using epitaxial deposition methods in the same reaction chamber under the same process conditions. Embodiments of the disclosure relate to structures and devices formed using such methods, and to apparatus for performing the methods and/or for forming the structure and/or devices.

In accordance with examples of the disclosure, a method of reducing interface resistance between silicon nanosheet layers and doped source/drain regions of a substrate is provided. An exemplary method includes providing a substrate within a reaction chamber, performing an etching process in the reaction chamber to form a silicon nanosheet recess in the silicon nanosheet layer, and performing first and second vapor depositions in the reaction chambers to deposit a first doping into the formed recess and a second doping into the source/drain region of the nanosheet device. The second doped material may be in contact with the first doped material. The substrate may comprise stacks including silicon nanosheet layers and SiGe layers.

In accordance with examples of the disclosure, the formed silicon nanosheet recess can be between about 0 and 10 nm or may be between about 1 and 7 nm. The deposited first doped material width may be between about 1 and 10 nm. The deposited first doped material width may be larger than the formed silicon nanosheet recess.

In accordance with further examples of the disclosure, the temperature within the reaction chamber may be less than 600° C. or between about 200° C. and 450° C., or between about 275° C. and 400° C. The pressure of the reaction chamber may be between 1 and 100 Torr or between about 10 Torr and about 70 Torr or about 30 Torr and about 60 Torr.

In yet an additional embodiment of the disclosure, the etching process may comprise etchants selected from the group consisting of Cl₂, HCl, Br₂, HI, HF, F₂, and I₂. In one example, the etchant flow rate of Cl₂ may between 1 and 2000 sccm, or between about 1 and 460 sccm or between 1 and 75 sccm. In an embodiment, the first deposited first doped material may comprise Si:B, Si:P, or SiGe:B.

Further described in the disclosure is a device which can be made by providing a substrate within a reaction chamber, performing an etching process in the reaction chamber to form a silicon nanosheet recess in the silicon nanosheet layer, and performing first and second vapor depositions in the reaction chambers to deposit a first doping into the formed recess and a second doping into the source/drain region of the nanosheet device. The second doped material may be in contact with the first doped material. The substrate may comprise stacks including silicon nanosheet layers and SiGe layers.

In accordance with further embodiments of the disclosure, a reaction chamber may be adapted to perform the method according to the present disclosure.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures, which show source/drain formation with reduced interface resistance during epitaxy steps.

FIG. 1 illustrates a silicon nanosheet structure during a source/drain epitaxy step in accordance with one or more embodiments of the disclosure.

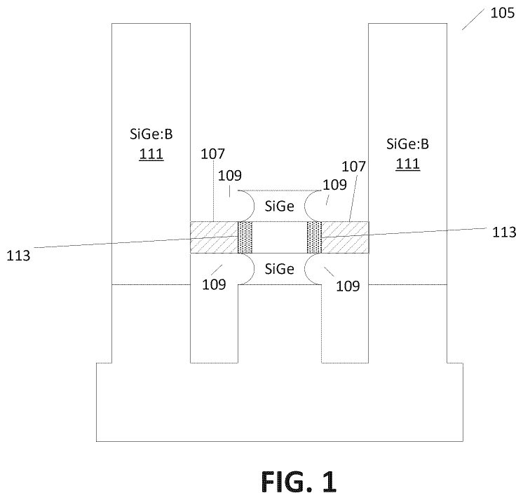

FIG. 2 illustrates a controlled etchback and deposition process in accordance with one or more embodiments of the disclosure.

FIGS. 3A-3D illustrate source/drain deposition profiles in accordance with one or more embodiments of the disclosure.

FIGS. 4A-4C illustrate gate-all-around device structures in accordance with one or more embodiments of the disclosure.

FIGS. 5A-5C illustrate complementary field effect transitory (CFET) device structures in accordance with one or more embodiments of the disclosure.

FIG. 6 illustrates a method for reducing interface resistance in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group IlI-V semiconductor materials, and can include one or more layers overlying or underlying the bulk material. The substrate can include various topologies, such as gaps, including recesses, lines, trenches, or spaces between elevated portions, such as fins, and the like, formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form, such as a powder, a plate, or a workpiece. Substrates in the form of a plate may include wafers in various shapes and sizes. Substrates may be made from materials, such as silicon, silicon germanium, silicon oxide, gallium arsenide, gallium nitride, and silicon carbide, for example.

A continuous substrate may extend beyond the bounds of a process chamber where a deposition process occurs and may move through the process chamber such that the process continues until the end of the substrate is reached. A continuous substrate may be supplied from a continuous substrate feeding system, allowing for the manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, the term “layer” can refer to any continuous or non-continuous structure and material. For example, a layer can include two-dimensional materials, three-dimensional materials, nanoparticles or even partial or full molecular layers or partial or full atomic layers or clusters of atoms and/or molecules. A layer may comprise material or a layer with pinholes, which may be at least partially continuous.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

In an aspect of the disclosure, precursors may include silane, disilane, trisilane, tetrasilane, dichlorosilane, pentachlorodisilane, monolodosilane, dilodosilane, tetrabromosilane, any other halogenated silane or higher-order silane molecule. In an embodiment, halogenated and hydride Boron precursors may also be utilized. In an embodiment, DCS flow may range between 20 and 1000 sccm, DiSilane flow may range between 1 and 1600 sccm, 1% B₂H₆/H₂ flow may range between 1 and 1000 sccm, x % Si₂Cl₅H₁/H₂ flow may range between 20 and 1000 sccm, and the Si₂Cl₅H₁ vessel temperature may range between 5 and 60 degrees Celsius. In another embodiment, DiSilane flow may be approximately 18 sccm, 1% B2H6/H2 flow may be approximately 12 sccm, and the Si2Cl5H1 vessel temperature may be approximately 45 degrees Celsius.

As used herein, the term “chemical vapor deposition” can refer to any process wherein a substrate is exposed to one or more volatile precursors, which react and/or decompose on a substrate surface to produce a desired deposition.

As used herein, the term “gate-all-around device” may refer to devices that include a conductive material wrapped around a semiconductor channel region. As used herein, the term “gate-all-around device” may also refer to a variety of device architectures, such as nanosheet devices, forksheet devices, vertical FETs, CFETs, and the like.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. It shall be understood that when a composition, method, device, or the like is said to comprise certain features, it means that it includes those features, and that it does not necessarily exclude the presence of other features, as long as they do not render the claim unworkable. This notwithstanding, the wording “comprises” includes the meaning of “consists of,” i.e., the case when the composition, method, device, etc. in question only includes the features, components, and/or steps that are listed, and does not contain any other features, components, steps, etc. In accordance with further aspects, substantially the same can mean within ±5%, ±1%, ±0.5%—e.g., atomic, volume, length, or the like, depending on the context.

In this disclosure, any defined meanings do not necessarily exclude ordinary and customary meanings in some embodiments.

The term “carrier gas” as used herein may refer to a gas that is provided to a reaction chamber together with one or more precursors and/or etchants. For example, a carrier gas may be provided to the reaction chamber together with one or more of the precursors and/or etchants used herein. Exemplary carrier gases include N2, H2, and noble gases such as He, Ne, Kr, Ar and Xe. By way of particular examples, the carrier gas can include one or more of nitrogen (N2), argon (Ar), helium (He), in any combination. For example, in various embodiments of this disclosure, an N2 carrier gas with a flow range of 5 to 30 slm may be utilized.

As opposed to a carrier gas, a purge gas may be provided to a reaction chamber separately, i.e., not together with one or more precursors. This notwithstanding, gases which are commonly used as a carrier gas may also be used as a purge gas, even within the same process. For example, in a cyclic deposition-etch process, N2 used as a carrier gas may be provided together with one or more precursors during deposition pulses, and N2 used as a purge gas may be used to separate deposition and etch pulses. Of course, N2 may be replaced by another suitable inert gas, such as H2, or a noble gas, such as He, Ne, Kr, Ar, and Xe. Hence, it is the manner of how a gas is provided to the reaction chamber that determines whether a gas serves as a purge gas or a carrier gas in a specific context. Thus, as used herein, the term “purge” may refer to a procedure in which an inert or substantially inert gas is provided to a reaction chamber in between two pulses of gases that may react with each other. For example, a purge, e.g., using nitrogen gas, may be provided between a precursor pulse and an etchant pulse, thus avoiding or at least minimizing gas phase reactions between the precursor and the etchant. It shall be understood that a purge can be affected either in time or in space, or both. For example, in the case of temporal purges, a purge step can be used, e.g., in the temporal sequence of providing a first precursor to a reaction chamber, providing a purge gas to the reaction chamber, and providing an etchant to the reaction chamber, wherein the substrate on which a layer is deposited does not move. In the case of spatial purges, a purge step can take, for example, the following form: moving a substrate from a first location to which a first precursor is (e.g., continually) supplied, through a purge gas curtain, to a second location to which a second precursor or etchant is (e.g., continually) supplied.

As set forth in more detail below, various steps of exemplary methods described herein can be performed in the same reaction chamber. In an embodiment, the reaction chamber may comprise an epitaxy reactor.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicated herein can be relative or absolute percentages.

A number of example materials are given throughout the embodiments of the current disclosure; it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the terms “under,” “underlying,” or “below” will be construed to be relative concepts.

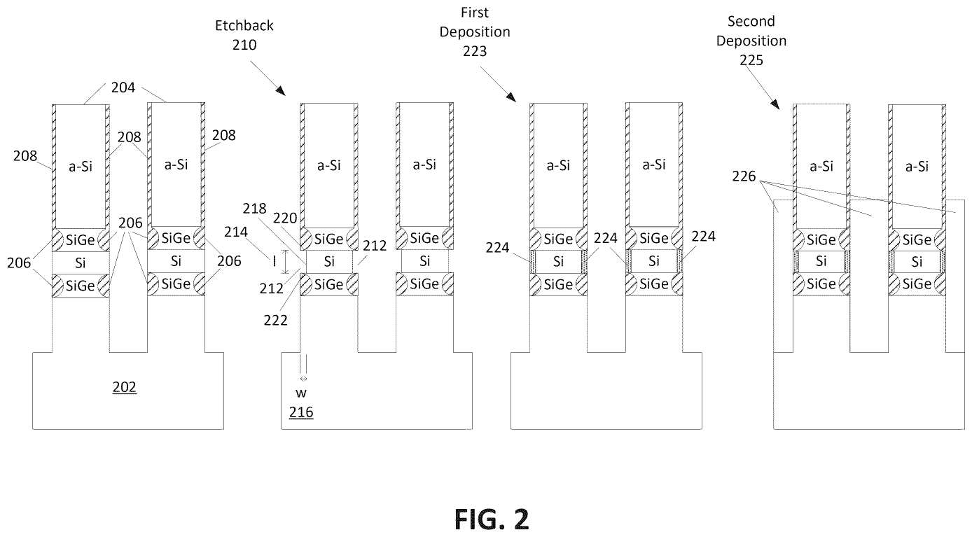

Disclosed are methods and systems for silicon nanosheet etchback to reduce source/drain and silicone nanosheet interface resistance using epitaxial deposition methods in the same reaction chamber under the same process conditions. Turning now to the figures, FIG. 2 illustrates a controlled etchback of silicon nanosheets to reduce interface resistance between the silicon nanosheets and the doped source/drain regions of a nanosheet device. In an embodiment, the etchback may be a Cl₂ thermal etchback.

In FIG. 2, a substrate 202 is provided within a reaction chamber. In an embodiment of the disclosure, the reaction chamber may be brought to a desired temperature and/or pressure to perform all steps of the etchback and deposition process. For example, the reaction chamber may maintain a temperature less than 600° C. or between about 200° C. and 450° C., or between about 275° C. and 400° C. during the etchback and deposition process. The reaction chamber pressure may be maintained between 1 and 100 Torr or between about 10 Torr and about 70 Torr or about 30 Torr and about 60 Torr during the etchback and deposition process.

The substrate may be precleaned to remove oxide and carbon from the substrate surface. The substrate 202 may comprise at least one silicon (Si), silicon germanium (SiGe) stack 204. The Si, SiGe stack 204 may include numerous silicon nanosheet layers and SiGe layers.

The Si, SiGe stack 204 may include formed silicon nanosheet inner spacers 206. The outer wall of the stack 204 may include a silicon nitride layer 208, which may potentially improve stack integrity and facilitate the later downstream removal of sacrificial SiGe layers, allowing for their replacement with a metal gate stack. The areas between the silicon nanosheet inner spacers 206 may experience minimal field effect in the finished nanosheet device. The high potential resistance between the silicon inner spaces 206 may not allow a gate to control the generated nanosheet device acceptably.

As shown if FIG. 2, an etching process 210 is performed in the reaction chamber. The etching process is performed on at least a portion of a silicon nanosheet to form a silicon nanosheet recess in the silicon nanosheet layer. In accordance with various embodiments of the disclosure, the etching process 210 may use an etchant selected from the group consisting of Cl₂, HCl, Br₂, HI, HF, F₂, and I₂. In some exemplary embodiments, any etchant that can thermally etch silicon may be used. The etchant may preferably be a halogen-based etchant.

In FIG. 2, a Cl₂ etchant may be used to form silicon nanosheet recess 212. The Cl₂ etchant flow rate may be between 1 and 2000 sccm, or between about 1 and 460 sccm or between 1 and 75 sccm.

The formed nanosheet recess 212 may have a length 214, which is defined by the nanosheet layer thickness, and a width 216, which may be between about 0 and 10 nm or between about 1 and 7 nm. In an embodiment of the disclosure, the formed nanosheet recess 212 width 216 may be fractions of a nanometer based on the performed etching of the nanosheet layer. The formed nanosheet recess 212 may comprise a sidewall surface 218, a top surface 220, and a bottom surface 222.

As shown in FIG. 2, a first vapor deposition process 223 may be performed in the reaction chamber to selectively deposit material with first doping into the formed silicon nanosheet recess 212. The deposited first doped material 224 may comprise a SiB deposit layer which may be highly conductive and provide improved valance matching. Alternatively, a low Ge content SiGe:B layer may also be selected for the deposited first doped material 224 in PMOS devices. For a NMOS device, a first doped material 224 may include SiP.

In an embodiment of the disclosure, the first doping may be between 1×10¹⁹ and 5×10²¹ at/cm³, preferably between 1×10¹⁹ to 3×10²¹ at/cm³, even more preferably 1×10²⁰ to 2×10²¹ at/cm³. The deposited first doped material width may be between about 1 and 10 nm. In another exemplary embodiment, the deposited first doped material width may be 1 nm. In yet another exemplary embodiment, the first doped material width may be larger than the formed silicon nanosheet recess 212.

Returning to FIG. 2, a second vapor deposition process 225 may be performed in the reaction chamber to selectively deposit material with a second doping 226 to fill a source/drain region of the substrate, the second doped material in contact with the first doped material. The second doped material may comprise SiGe:B, which may be in contact with the first doped material, including SiB. In some embodiments, the first doped material and second doped material may be the same material or different materials, with the same or different doping. In an embodiment of the disclosure, the second doping may be between 1×10¹⁷ and 9×10²¹ at/cm³, preferably between 5×10²⁰ to 6×10²¹ at/cm³, even more preferably 1×10²¹ to 5×10²¹ at/cm³.

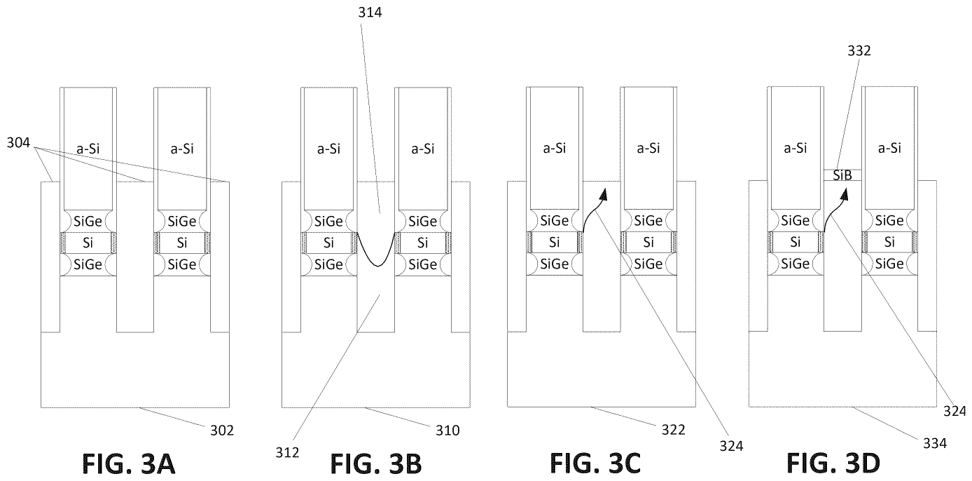

FIGS. 3A-3D illustrate source/drain deposition profiles in accordance with various embodiments of the disclosure. In FIG. 3A, a second vapor deposition using a second doped material 304 is used to fill a source/drain region of substrate 302, the second doped material in contact with a first doped material. In FIG. 3A, the second doped material may comprise SiGe:B, which may be in contact with the first doped material, including SiB 306. In some embodiments, the first doped material and second doped material may be the same material or different materials, with the same or different doping. In some embodiments, such as for CFET and GAA devices, the source/drain may also be contacted from the backside of the wafer.

FIG. 3B illustrates selective deposition of both 1) a SiGe:B higher content Ge layer and 2) a SiGe:B lower content Ge layer to fill a source/drain regions of substrate 310. For instance, as illustrated in FIG. 3B, a first region 312 of a source/drain region may comprise a low Ge content SiGe:B layer for filing the first region 312 of the source/drain region. The low Ge content may be between 0% and 80%, more preferably between 0% and 50%, most preferably between 0% and 35%.

The second region 314 of a source/drain region may comprise a high Ge content SiGe:B layer for filing the second region 314 of the source/drain region. The high Ge content may be between 0% and 100%, more preferably between 20% and 90%, most preferably between 60% and 90%.

FIG. 3C illustrates a continuously graded Ge content of SiGe:B for selective deposition of source/drain materials of substrate 322. In an embodiment of the disclosure, the Ge content may be continuously graded down to the Ge content level of the silicon nanosheet. The continuously graded Ge content 324 of SiGe:B may assist with overcoming any energy barrier generated from valance band differences.

FIG. 3D illustrates a continuously graded Ge content 324 of SiGe:B and a SiB cap 332 for selective deposition of source/drain materials of substrate 334.

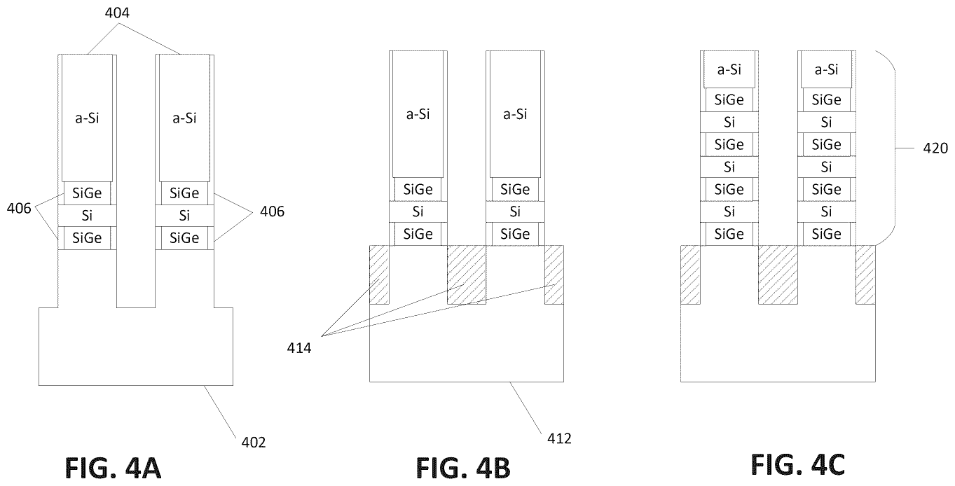

FIGS. 4A-4C illustrate gate-all-around device structures (GAA) in accordance with one or more embodiments of the disclosure. In FIG. 4A a substrate 402 is provided within a reaction chamber. The substrate may be precleaned to remove oxide and carbon from the substrate surface. The substrate 402 may comprise at least one silicon (Si), silicon germanium (SiGe) stack 404. The Si, SiGe stack 404 may include square SiN inner spacers 406. In an embodiment, the inner spacers 406 may include SiCN, SiOCN, and/or other dielectric materials.

FIG. 4B illustrates the addition of a dielectric 414 in the subfin area to prevent damage from Cl₂ etching. The dielectric may include SiOx, SiN, AlOx, TiN or the like. In another embodiment, other protective dielectric or non-dielectric materials such as Si and SiGe may also be used. In an embodiment substrate 412 may be counter-doped to prevent parasitic current leakage paths in the finished device which may degrade performance. In an embodiment, for NMOS device, the Si substrate may be p-type doped and PMOS devices the substrate subfin may be n-type doped.

FIG. 4C illustrates additional silicon nanosheets, SiGe layers 420 that may be used in various gate-all-around devices.

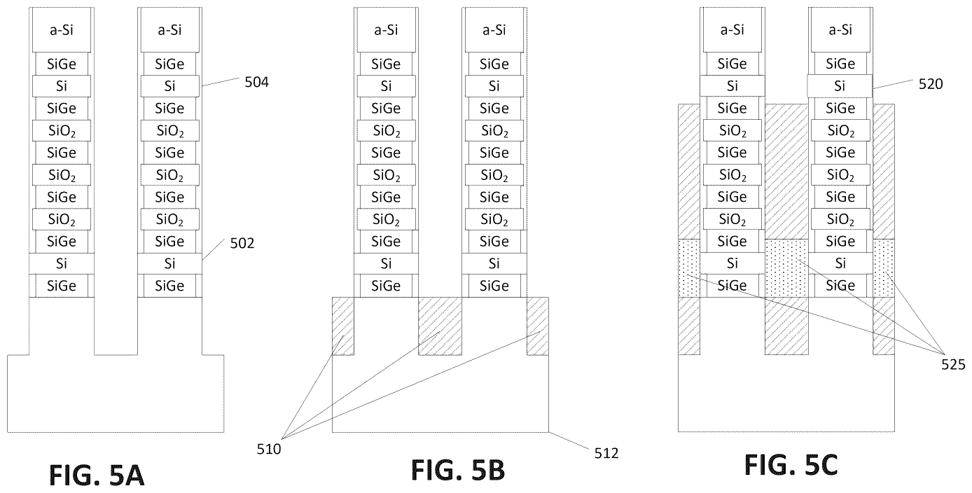

FIGS. 5A-5C illustrate complementary field-effect transistors (CFET) devices structures in accordance with one or more embodiments of the disclosure. In FIG. 5A, the bottom silicon nanosheet 502 is exposed whereas, the top silicon nanosheet 504 is covered. In FIG. 5B, a dielectric 510 has been added to the subfin area of substrate 512. In FIG. 5C, the top silicon nanosheet 520 is exposed and source/drain deposition has occurred in the bottom silicon nanosheet region 525.

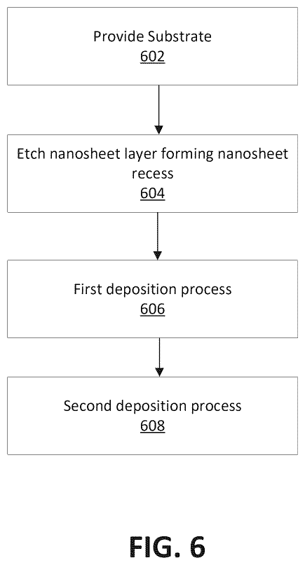

FIG. 6 illustrates a method of reducing interface resistance in accordance with embodiments of the disclosure. In an aspect of the disclosure, the method and system reduce the interface resistance between a source/drain and silicon nanosheet channels of a nanosheet device during the epitaxy process (EPI) using a single reaction chamber.

In step 602, a substrate is provided within a reaction chamber. The substrate comprises at least one stack, the at least one stack including silicon nanosheet layers and SiGe layers.

An etching process is performed in the reaction chamber on at least a portion of a silicon nanosheet layer to form a silicon nanosheet recess in the silicon nanosheet layer as shown in step 604. In step 606, a first vapor deposition process is performed in the reaction chamber to selectively deposit a material with a first doping into the formed silicon nanosheet recess. In step 608, a second vapor deposition process is performed in the reaction chamber to selectively deposit material with a second doping to fill a source/drain region of the substrate, the second doped material in contact with the first doped material. In an embodiment of the disclosure, each of process steps 602 through 608 may be performed in the same reaction chamber under the same process conditions.

In an embodiment of the discourse, a graph of the finished device's maximum drive current (ID, SAT) versus gate voltage (VG) can be generated after reducing the interface resistance using the steps outlined in FIG. 6. The generated graph may illustrate that if a silicon nanosheet can be etched under the silicon nitride inner spacers to form a silicon nanosheet recess, and the formed silicon nanosheet recess can be doped with a SiB layer, the maximum drive current can be increased. The graph may further illustrate that the width of the formed recess channel may not be oversized, as the doped material deposited in the formed recess should not contact the gate of the finished nanosheet device; otherwise, a short channel effect may occur, possibly preventing the finished nanosheet device from turning off.

For purposes of summarizing the invention and the advantages achieved over the prior art, certain objects and advantages of the invention have been described above. It is to be understood, however, that not all such objects or advantages may necessarily be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method of reducing interface resistance between silicon nanosheet layers and doped source/drain regions of a substrate, the method comprising:
providing the substrate within a reaction chamber, the substrate comprising stacks including silicon nanosheet layers and SiGe layers;
performing an etching process in the reaction chamber on at least a portion of a silicon nanosheet layer to form a silicon nanosheet recess in the silicon nanosheet layer;
performing a first vapor deposition process in the reaction chamber to selectively deposit a material with a first doping into the formed silicon nanosheet recess; and
performing a second vapor deposition process in the reaction chamber to selectively deposit a material with a second doping to fill a source/drain region of the substrate, the second doped material in contact with the first doped material.

2. The method of claim 1, wherein the formed silicon nanosheet recess is between about 0 and 10 nm or is between about 1 and 7 nm.

3. The method of claim 1, wherein the deposited first doped material width is between about 1 and 10 nm.

4. The method of claim 1, wherein the deposited first doped material width is 1 nm.

5. The method of claim 2, wherein the deposited first doped material width is larger than the formed silicon nanosheet recess.

6. The method of claim 1, wherein the temperature within the reaction chamber is less than 600° C. or between about 200° C. and 450° C., or between about 275° C. and 400° C.

7. The method of claim 1, wherein the pressure within the reaction chamber is between 1 and 100 Torr or between about 10 Torr and about 70 Torr or about 30 Torr and about 60 Torr.

8. The method of claim 1, where the step of performing an etching process comprises providing an etchant selected from the group consisting of Cl₂, HCl, Br₂, HI, HF, F₂, and I₂.

9. The method of claim 8, where the etchant comprises Cl₂.

10. The method of claim 9, where the etchant flow rate of Cl₂ is between 1 and 2000 sccm, or between about 1 and 460 sccm or between 1 and 75 sccm.

11. The method of claim 1, wherein the deposited first doped material comprises SiB or SiP or SiGe:B.

12. The method of claim 1, wherein the deposited second doped material used to fill the source/drain region comprises any doped material constituting of Si or SiGe (Si1Ge1-x) where dopants may include p-type (holes) (B, Ga, Al) or N-Type (electron donors) (P, Ab, As, Sb).

13. The method of claim 1, wherein the deposited second doped material used to fill the source/drain region comprises SiGe:B.

14. The method of claim 1, wherein the source/drain region comprises a first region and a second region.

15. The method of claim 14, wherein the first region of source/drain region comprises a low Ge content of SiGe:B for filing the first region of the source/drain region.

16. The method of claim 14, wherein the second region of source/drain region comprises a high Ge content of SiGe:B for filing the second region of the source/drain region.

17. The method of claim 14, wherein the Ge content of SiGe:B for filing the first and second source/drain region comprises a continuously graded Ge content of the SiGe:B across the first and second source/drain regions.

18. The method of claim 17, wherein the source/drain region includes a SiB layer on top of the source/drain region to terminate growth.

19. A device made by performing the steps of:
providing a substrate within a reaction chamber, the substrate comprising stacks including silicon nanosheet layers and SiGe layers;
performing an etching process in the reaction chamber on at least a portion of a silicon nanosheet layer to form a silicon nanosheet recess in the silicon nanosheet layer;
performing a first vapor deposition process in the reaction chamber to selectively deposit a highly doped material into the formed silicon nanosheet recess; and
performing a second vapor deposition process in the reaction chamber to selectively deposit a doped material to fill a source/drain region of the substrate, the doped material in contact with the highly doped material.

20. The device of claim 19 wherein the device comprises a gate-all-around device or a complementary field effect transistor device.

21. A reaction chamber adapted to perform the steps of:
providing the substrate within a reaction chamber, the substrate comprising stacks including silicon nanosheet layers and SiGe layers;
performing an etching process in the reaction chamber on at least a portion of a silicon nanosheet layer to form a silicon nanosheet recess in the silicon nanosheet layer;
performing a first vapor deposition process in the reaction chamber to selectively deposit a material with a first doping into the formed silicon nanosheet recess; and
performing a second vapor deposition process in the reaction chamber to selectively deposit a material with a second doping to fill a source/drain region of the substrate, the doped material in contact with the highly doped material.
